(19) United States
(12) Patent Application Publication
(10) Pub. No.: US 2005/0118447 A1
(43) Pub. Date: Jun. 2, 2005

(54) Stiffener, a method of manufacturing a stiffener, and a semiconductor device with a stiffener

(75) Inventor: Masahiro Omachi, Itami-Shi (JP)

Correspondence Address: DARBY & DARBY P.C., P. O. BOX 5257, NEW YORK, NY, 10150-5257, US

(73) Assignee: Sumitomo Electric Industries, Ltd.

(21) Appl. No.: 10/937,201

(22) Filed: Sep. 8, 2004

(30) Foreign Application Priority Data
Sep. 19, 2003 (JP) 2003-328719

(51) Int. Cl. H01L 23/02

(52) U.S. Cl. 428/596; 29/412; 428/687; 257/678

(57) ABSTRACT

The object of the present invention is to provide: a novel stiffener with superior cosmetic appearance and adhesive qualities and that is easy to make; a method for making the same; and a semiconductor device using this stiffener.

A stiffener 1 is punched from a plate material 10. The outer perimeter end surface thereof is formed with shear surfaces and fracture surfaces created by the punching operations and abraded surfaces extending along the thickness axis of the plate created by the abrasion of projections on the fracture surfaces. In the method for making the stiffener, the stiffener is formed by being punched from the plate material 10. Then, it is re-fitted to the punched hole 10a of the plate material 10 and removed from the plate material 10 once more. The semiconductor device is reinforced using this stiffener 1.

### INCORPORATION BY REFERENCE

The present application claims priority under 35 U.S.C. §119 to Japanese Patent Application No. 2003-328719 filed on Sep. 19, 2003. The content of the application is incorporated herein by reference in its entirety.

### BACKGROUND OF THE INVENTION

1. Field of the Invention

The present invention relates to a stiffener and method for making the same and a semiconductor device reinforced using this stiffener.

2. Description of the Background Art

In order to handle higher scales of integration in semiconductor elements and the accompanying higher-density packages and greater number of pins, the use of BGA (Ball Grid Array) semiconductor devices, in which solder balls are used for substrate mounting, is becoming widespread. In BGA semiconductor devices, a BGA, in which solder balls are arranged in a grid structure, is disposed on one side of a package, and a semiconductor element is mounted on a mounting section disposed on the same side or the opposite side of the package. Each electrode of the mounted semiconductor element is connected to an individual BGA solder ball by way of bonding wire, solder balls, or a conductor circuit formed on the package.

In these types of BGA semiconductor devices, there is a need for the package to be as flat as possible especially when the semiconductor element is to be mounted on the mounting section, when the semiconductor device is to be mounted on a substrate using a BGA, or the like. In order to maintain the flatness of the package and to improve heat dissipation of the package so that heat can be dissipated from the semiconductor element, a plate-shaped stiffener formed from a metal or the like may be adhered to the package. (See, for example, Japanese laid-open patent publication number Hei 11-204584, Japanese laid-open patent publication number Hei 11-220055, and Japanese laid-open patent publication number 2000-286363.

Stiffeners are generally punched to a predetermined flat shape from a material such as a metal plate. Also, different types of surface treatment are applied to the stiffener surface in order to remove burring that takes place at the outer perimeter edges during the punching process, to clean and remove press oil adhered to the surface, to improve adhesion of an adhesion surface on one side for securing to the package as described above, or to improve cosmetic appearance on the other side while also improving the ease of printing on that surface so that the surface can be used as a display surface for product numbers, manufacturer names, and the like.

Generally, in conventional methods for making stiffeners,
(1) surface treatment is applied to both sides of the material before punching is performed, and then the stiffener is punched to a predetermined flat shape; or, conversely, (2) the stiffener is punched to a predetermined flat shape, followed by applying surface treatment to both sides of the stiffener.

However, in procedure (1), the surfaces treated ahead of time can be contaminated by press oil during the punching operation, leading to lower adhesive properties for the adhesive surface and to inferior cosmetic appearance for the display surface. Also, the treated surfaces can be damaged from contact and friction with metal during the punching operation. Furthermore, since there will be multiple, separate stiffeners after the punching operation, handling during subsequent operations (printing on the display surface, adhering to packages, and the like) can lead to stiffeners striking and rubbing against each other so that the treated surfaces are damaged or blemished.

With the procedure (2) also, multiple, separate stiffeners can strike and rub against each other during subsequent surface treatment operations, printing operations, and package adhesion operations, leading to damages and blemishes. Furthermore, separated stiffeners are less easy to handle, and surface treatment of both sides of individual stiffeners becomes difficult. In particular, providing different surface treatments for the front and back surfaces requires masking to be applied to the surface not being treated for each individual stiffener, making the surface treatment operation significantly more complex and increasing production costs.

### SUMMARY OF THE INVENTION

The object of the present invention is to provide a new stiffener that provides good cosmetic appearance, good adhesive characteristics, and that is easy to make. Another object of the present invention is to provide a method for making this type of stiffener. Yet another object of the present invention is to provide a semiconductor device using this stiffener.

A first implementation of the invention provides a flat stiffener used to reinforce semiconductor devices. The stiffener is formed in a predetermined flat shape from a plate material by punching. An outer perimeter end surface of the stiffener is formed with shear surfaces and fracture surfaces created by the punching operations, and abraded surfaces extending along the thickness axis of the plate created by abrasion of projections on the fracture surfaces.

A second implementation of the invention provides a stiffener as described in the first implementation on which surface treatment is applied to both surfaces of the plate.

A third implementation of the invention provides a stiffener as described in the second implementation on which different surface treatments are applied to the surfaces of the plate.

A fourth implementation of the invention provides a stiffener as described in the second implementation in which at least one type of surface treatment out of the following list is applied to the surfaces of the plate: sandblasting; high-pressure washing; Ni plating; zinc plating; chromating; alumetizing; alodining; Au plating; and oxide film application.

A fifth implementation provides a stiffener as described in the second implementation in which bleeding of the surface treatment to the outer perimeter end surface is less than 20% of the area of the outer perimeter end surface.

A sixth implementation of the invention provides a stiffener as described in the first implementation formed from Fe, Cu, Al, an alloy of the metals, or a compound containing the metals.

A seventh implementation provides a method for making a stiffener as described in the first implementation including: a step for forming a stiffener having a predetermined flat shape by punching a plate material; a step for re-fitting the formed stiffener in a punched hole in the plate material; a step for applying a predetermined surface treatment to at least one side of the stiffener that has been re-fitted and integrated with the plate material; and a step for removing the stiffener from the plate material once more after treatment.

A eighth implementation provides a semiconductor device reinforced using a stiffener from the first implementation.

As described in the seventh implementation, the stiffener in the first implementation provides a stiffener punched from a plate material and formed with a predetermined flat shape. Then, the formed stiffener is re-fitted to the punched hole of the plate material. The re-fitted stiffener integrated with the plate material is provided with surface treatment on both surfaces, and the treated stiffener is removed from the plate material once more.

As a result, the outer perimeter end surface of the stiffener is formed, as descried in the first implementation, with shear surfaces and fracture surfaces created by the punching operations, and abraded surfaces extending along the thickness axis of the plate created by abrasion of projections on the fracture surfaces. Since the stiffener according to the present invention is made by applying surface treatment after the punching operation, press oil adhered to the surface and abrasion and damage caused by contact with the die can be cleanly removed by the subsequent surface treatment operation.

Also, with the present invention, the stiffener described above undergoes subsequent steps in a state where it has been re-fitted to the punched hole and integrated with the plate material. Furthermore, since multiple stiffeners are generally formed from a single plate material, the stiffeners can be re-fitted to multiple punched holes so that multiple stiffeners integrated in a single plate material can undergo subsequent steps all together. In other words, surface treatment and the like can be applied while using the plate material as a support tool supporting one or more stiffeners.

As a result, it is possible to reliably prevent nicking and damage from stiffeners striking or rubbing against each other as would occur if multiple stiffeners were handled as separate pieces. Also, since the stiffeners can be handled without directly touching the stiffeners themselves, ease of handling is improved, e.g., for surface treatment and transporting.

When providing this kind of support, the plate material is in contact with only the outer perimeter end surface of the stiffener. Thus, for the surfaces on which surface treatment is to be applied, the entire surface can be exposed without any obstructions that would form shadows. Thus, as indicated in the second implementation, applying surface treatment to both sides of the stiffener is made easy.

By applying a material, e.g., a protective masking material, to the entire plate material including the stiffener, on the side opposite from the surface to be treated, the surface treatment is prevented from bleeding onto the opposite surface while surface treatment is allowed for just one side. Also, it would be easy to selectively form masks on just the surface opposite the surface to be treated, thus allowing surface treatment to be performed on just one side of the stiffener. Thus, as indicated in the third implementation, different surface treatments can be applied easily for the two sides of the stiffener.

As described in the fourth implementation, surface treatments can be at least one type of surface treatment out of the following list: sandblasting; high-pressure washing; Ni plating; zinc plating; chromating; alumetizing; alodining; Au plating; and oxide film application. Also, since the plate material is in contact with the outer perimeter end surface of the stiffener that has been re-fitted as described above, the plate material also serves to prevent the surface treatment from bleeding onto the outer perimeter end surface. Thus, as described in the fifth implementation, bleeding of the surface treatment onto the outer perimeter end surface can be kept to less than 20% of the area of the outer perimeter end surface.

Taking into account the fact that the stiffener serves to maintain flatness of the package of the semiconductor device and to improve heat dissipation, the stiffener can be formed from Fe, Cu, Al, an alloy of these metals, or a compound containing these metals, as described in the sixith implementation. Also, with the method for making the present invention in seventh implementation, a stiffener having the superior characteristics described above can be made. Furthermore, with the invention in the eighth implementation, a stiffener having superior characteristics as described above can be used to provide a semiconductor device with good cosmetic appearance and improved reinforcement.

The above, and other objects, features and advantages of the present invention will become apparent from the following description read in conjunction with the accompanying drawings, in which like reference numerals designate the same elements.

### BRIEF DESCRIPTION OF THE DRAWINGS

FIGS. 1A and 1B are perspective drawings showing steps in an example of a method for making stiffeners according to the present invention;

FIGS. 2A and 2B are perspective drawings showing steps subsequent to the above steps;

FIG. 3A is a cross-section drawing showing the structure of a press die used in a step for punching and re-fitting;

FIGS. 3B and 3C are cross-section drawings showing punching and re-fitting steps using this press die;

FIG. 4A through FIG. 4C are cross-section drawings showing steps subsequent to the ones above;

FIGS. 5A and 5B are cross-section detail drawings showing a simplified view of the outer perimeter end surface of a stiffener according to the present invention;

FIG. 6A is a perspective drawing showing an exterior view of a semiconductor device according to the present invention that uses the stiffener described above;

FIG. 6B is a cross-section drawing of the semiconductor device;

FIG. 7 is an enlarged scanning electron microscope photograph of the outer perimeter end surface of a stiffener according to a first embodiment of the present invention immediately after being punched from a plate material;

FIG. 8 is a scanning electron microscope photo as in FIG. 7 but with the end section of a fracture surface enlarged further;

FIG. 9 is a scanning electron microscope photo with the outer perimeter end surface enlarged when a stiffener according to the first embodiment has been re-fitted to the punched hole of the plate material and then removed from the plate material once more;

FIG. 10 is a scanning electron microscope photo as in FIG. 9 but with the end section of a fracture surface enlarged further;

FIG. 11 is a scanning electron microscope photo with the outer perimeter end surface enlarged when a stiffener according to the first embodiment has been re-fitted to the punched hole of the plate material, has received surface treatment on both sides, and then has been removed from the plate material once more;

FIG. 12 is a scanning electron microscope photo with the outer perimeter end surface enlarged when a stiffener from a second embodiment has just been punched from the plate material;

FIG. 13 is a drawing illustrating the distribution of the different surfaces in FIG. 12;

FIG. 14 is a scanning electron microscope photo with the outer perimeter end surface enlarged when a stiffener from a second embodiment has been re-fitted to the punched hole of the plate material and removed once more;

FIG. 15 is a drawing illustrating the distribution of the different surfaces in FIG. 14;

FIG. 16 is a scanning electron microscope photo in which an abraded surface formed on a fracture surface in FIG. 14 is further enlarged;

FIG. 17 is a drawing illustrating the distribution of the different surfaces in FIG. 16; and

FIG. 18 is a scanning electron microscope photo showing an enlarged view of the boundary between the surface and the outer perimeter end surface when a stiffener according to the second embodiment has been re-fitted to the punched hole of the plate material, has received surface treatment on both sides, and then has been removed from the plate material once more.

### DETAILED DESCRIPTION OF THE INVENTION

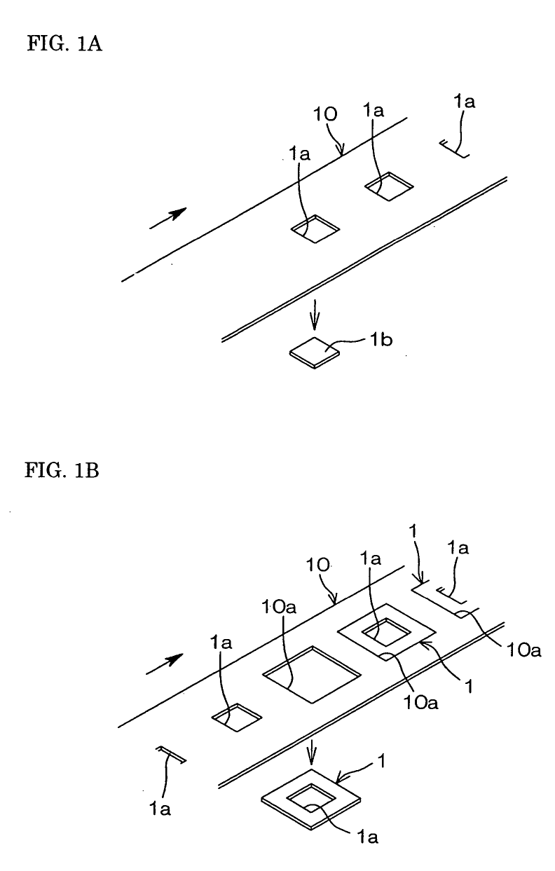

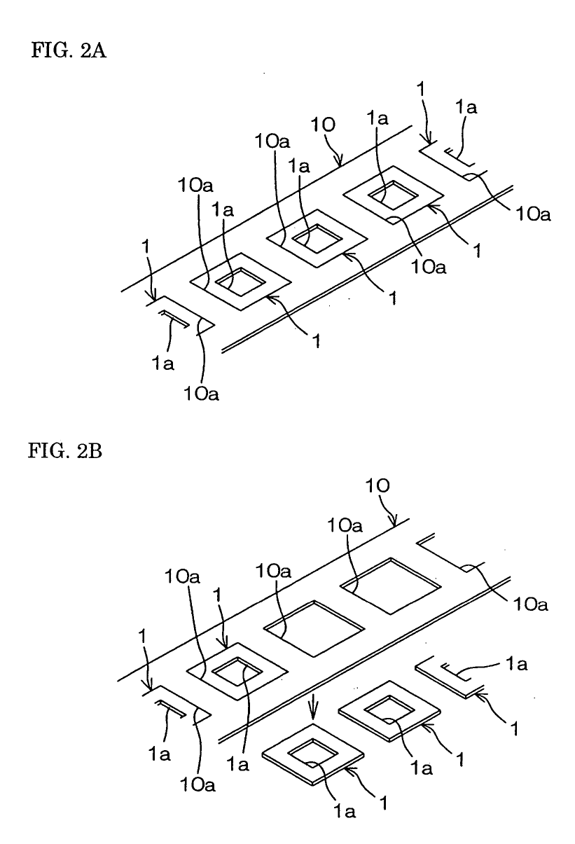

FIGS. 1A, 1B, 2A and 2B are perspective drawings showing steps performed in an example of a method for making a stiffener according to the present invention. As the figures show, a stiffener 1 made according to this sample method is flat and has a roughly square outer shape with a roughly square-shaped through-hole 1a at the center thereof. In the method shown in the figures, the stiffeners 1 are made from a long, band-shaped plate material 10 that allows multiple stiffeners 1 to be punched along its length.

The stiffener 1 and the plate material 10 from which it is made can be formed, as described above, from materials conventionally known for making forming stiffeners such as Fe, Cu, Al, alloys of these metals, or composite materials containing these metals. Specific examples include: stainless steel plates or steel plates, e.g., SPCC, copper or copper alloy plates, aluminum or aluminum alloy plates, and composite Al—SiC plates.

First, the plate material 10 is intermittently conveyed lengthwise as indicated by the solid arrow in FIG. 1A while a press die not shown in the figure is used to continuously perform punching operations, thus forming multiple through-holes 1a at uniform intervals. The punched piece 1b created during the formation of the though-hole 1a is removed in the figures, but it would also be possible to have it re-fitted to the through-hole 1a.

Next, the plate material 10 is intermittently conveyed lengthwise as indicated by the solid arrow in FIG. 1B while a press die not shown in the figure is used to continuously perform punching operations at the same pitch used to form the through-holes 1a, forming the stiffeners 1, which are then re-fitted to punch holes 10a in the plate material 10 so that the plate material 10 is re-integrated.

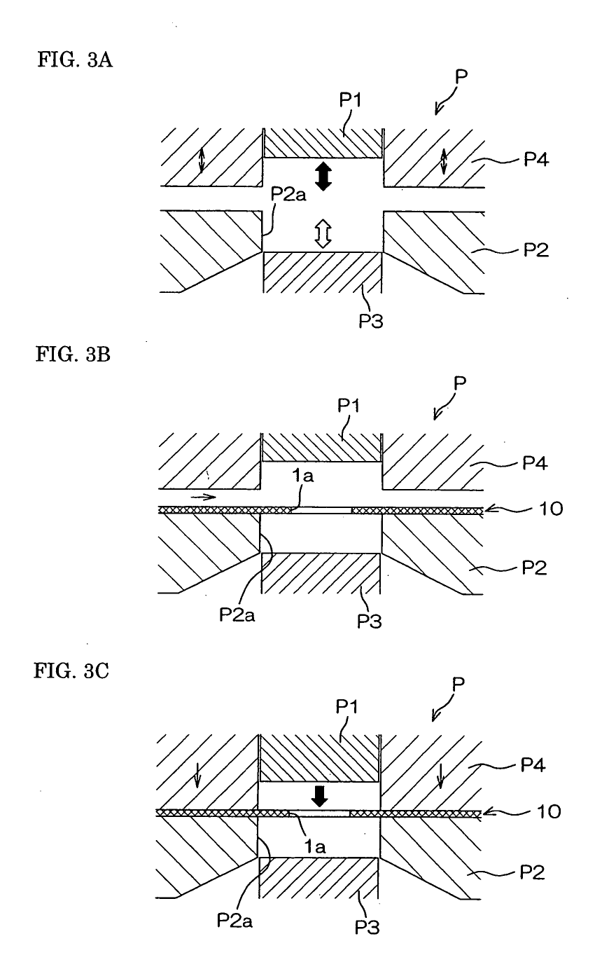

FIG. 3A is a cross-section drawing showing an example of a press die P used to punch the stiffener 1 from the plate material 10 and then re-fit it to the punched hole 10a during the operation shown in FIG. 1B. This press die P is equipped with: an upper movable die P1 moving vertically in the direction indicated by the black arrow in the figure and having a cross-section shape corresponding to the outer shape of the stiffener 1; a lower stationary die P2 formed with a through-hole P2a into which the upper movable die P1 is inserted; a lower movable die P3 moving vertically in the direction indicated by the white arrow in the figure and positioned below the upper movable die P1; and a holding die P4 moving vertically as indicated by the arrows in the figure and positioned so that it surrounds the perimeter of the upper movable die P1.

With the plate material 10 mounted on the lower stationary die P2 as shown in FIG. 3B, the upper movable die P1 is lowered into the through-hole P2a to punch the stiffener 1 from the plate material 10. The lower movable die P3 is used to re-fit the stiffener 1 punched by the upper movable die P1 and the lower stationary die P2 into the punched hole 10a of the plate material 10. The holding die P4 is used to secure the plate material 10 between itself and the lower stationary die P2 when the stiffener 1 is punched by the upper movable die P1 and the lower stationary die P2 and when the punched stiffener 1 is re-fitted to the punched hole 10a by the lower movable die P3.

In punching and re-fitting the stiffener 1 using the press die P as described above, the plate material 10 is first mounted on the lower stationary die P2 as shown in FIG. 3B. The plate material 10 is aligned so that the through-hole 1a formed in the plate material 10 during the previous step is positioned at the center of the stiffener 1 to be punched. When the long, band-shaped plate material 10 described above is used, the through-hole 1a can be aligned in this manner by, for example, restricting shifting along the width axis using a guide or the like not shown in the figure and using a feeding device also not shown to feed the material to the press die P at a pitch that matches the pitch for the stiffener 1 set up ahead of time.

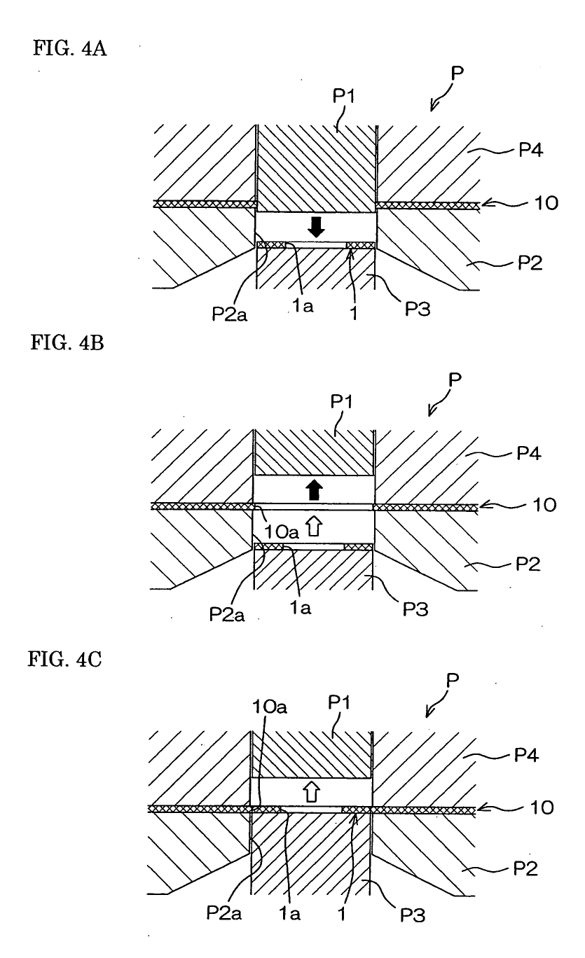

Next, the holding die P4 is lowered as shown in FIG. 3C, the plate material 10 is secured between it and the lower stationary die P2, and the upper movable die P1 is lowered into the through-hole P2a as shown in FIG. 4A. This results in the stiffener 1 being punched from the plate material 10. The punched stiffener 1 drops onto the lower stationary die P3. Next, the upper movable die P1 is raised above the plate material 10 as shown in FIG. 4C, and the lower movable die P3 is raised to a position where the upper surface thereof is aligned with the upper surface of the lower stationary die P2, as shown in FIG. 4C. This allows the stiffener 1 mounted on the lower movable die P3 to be re-fitted to the punched hole 10a of the plate material 10.

During this operation, the stiffener 1 mounted on the lower movable die P3 can be re-fitted to the punched hole 10a of the plate material 10 with further reliability by having the upper movable die P1 lowered to a position where the lower surface thereof is aligned with the lower surface of the holding die P4.

Next, the lower movable die P3 is lowered and the holding die P4 is raised so that the state shown in FIG. 3B is restored. Then, using the feeding device described above or the like, the plate material 10 is fed in the direction indicated by the arrow based on the pitch at which the stiffeners 1 are formed. The steps from FIG. 3C through FIG. 4C are then repeated. As a result, multiple stiffeners 1 can be formed as shown in FIG. 2A so that they are re-fitted to and integrated with the plate material 10.

Next, from the state shown in FIG. 2A, surface treatment is performed at least on one side of the two sides of the multiple stiffeners 1 supported on the plate material 10. Then, the stiffeners 1 can be removed again from the plate material 10, resulting in the stiffener 1 of the present invention.

The stiffeners 1 according to the present invention made as described above will have shear surfaces and fracture surfaces resulting from the punching operation. There will also be abrasion surfaces along the thickness axis of the plate resulting from friction of the projections of the fracture surfaces during the re-fitting of stiffener 1 into the punched hole 10a of the plate material 10 as well as during the removal of the stiffener 1 from the plate material 10.

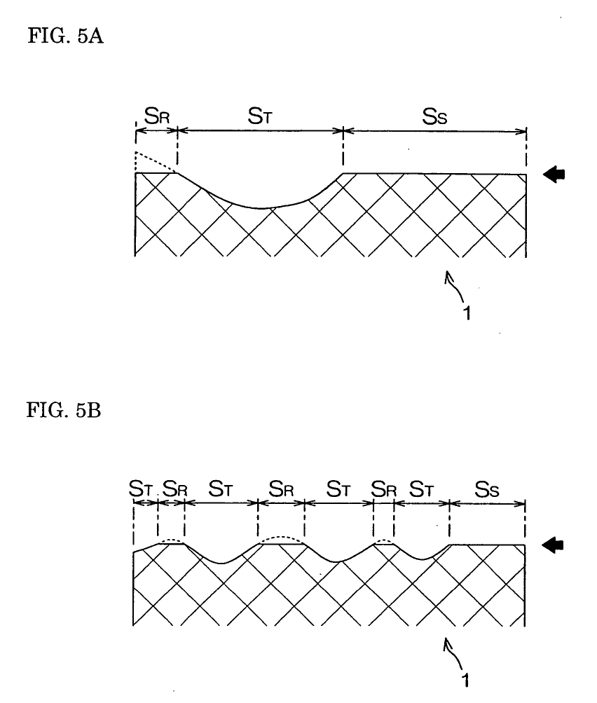

FIGS. 5A and 5B are cross-section detail drawing showing simplified views of the state of the outer perimeter end surfaces of the stiffener 1 of the present invention. The black arrows in these figures indicate the direction of the punching operation performed by the upper movable die P1 of the press die P. In other words, the right side of the figures correspond to the upper side of FIG. 3A, and the left side corresponds to the lower side. Of these figures, FIG. 5A shows the state of the outer perimeter end surface of the stiffener 1 when it is made from a plate material formed from a ductile material such as Fe, Cu, Al, or an alloy of these metals, e.g., a material in which the ratio σ_{0.2}/σₘₐₓ is no more than 0.8, where σ_{0.2} is 0.2% proof stress and σₘₐₓ is tensile strength.

As shown in the figure, when punching takes place from the direction indicated by the black arrows, shearing takes place up to almost half the thickness axis, and then significant fracturing takes place in the ductile material. As a result, roughly half the outer perimeter end surface of the stiffener 1 immediately after the punching operation forms shearing surfaces S_{S}, while the other half forms fracture surfaces S_{T}. After the stiffener 1 is refitted to the punched hole 10a of the plate material 10, surface treatment is applied, and the stiffener 1 is removed from the plate material 10, the outer perimeter end surface includes abrasion surfaces S_{R} along the thickness axis of the plate, resulting from sliding friction between projections on the fracture surfaces S_{T}, indicated by dotted lines in the figure, and the inner perimeter surfaces of the punched hole 10a.

In FIG. 5B shows the outer perimeter end surface of the stiffener 1 when the stiffener 1 and the plate material 10 from which it is made is formed from a brittle material such as a composite Al—SiC material, e.g., a material where the σ_{0.2}/σₘₐₓ ratio described above exceeds 0.8. As the figure shows, when punched from the direction indicated by the black arrow in the figure, the brittle material breaks so that shearing takes place over a very short range along the thickness axis, followed by a wave-like fracture pattern.

As a result, the outer perimeter end surface of the stiffener 1 immediately after the punching operation is formed with a smaller shearing surface S_{S} and much wider fracture surfaces S_{T}. When the stiffener 1 is re-fitted to the punched hole 10a of the plate material 10, surface treatment is applied, and the stiffener 1 is removed from the plate material 10, the outer perimeter end surface is also formed with abrasion surfaces S_{R} along the thickness axis of the plate, resulting from sliding friction between projections on the fracture surfaces S_{T}, indicated by dotted lines in the figure, and the inner perimeter surfaces of the punched hole 10a.

As a result, a stiffener according to the present invention can be identified by observing the outer perimeter end surface. More specifically, the outer perimeter end surface can be observed using a scanning electron microscope or the like, and if the outer perimeter end surface is formed with shearing surfaces S_{S}, fracture surfaces S_{T} and abrasion surfaces S_{R} created by punching, then it can be assumed that it is a stiffener 1 according to the present invention made by following the steps described above.

Examples of surface treatments applied to at least one of the two sides of the stiffener 1 when it has been re-fitted to the punched hole 10a of the plate material 10 include: sandblasting; high-pressure washing; Ni plating; zinc plating; chromate processing; alumetizing; alodining; Au plating; and oxide film application.

Among these, the use of sandblasting and high-pressure washing can remove press oil adhesed to the surface during punching. Also, sandblasting can remove burring created during punching and can improve adhesive properties by providing uniform surface roughness on the adhesive surface of the stiffener 1. Furthermore, the print characteristics of the display surface can be improved and a uniform cosmetic appearance can be provided. Applying an oxide film can improve the adhesive properties of the adhesive surface. Applying other treatments can improve the cosmetic appearance of the display surface. The surface treatment applied to one surface can also be a combination of two or more of the above treatments.

Also, as described above, surface treatment can be performed either on both sides of the stiffener 1, or different surface treatments can be performed on the two sides. For example, surface treatment suitable for a display surface can be performed on one side while surface treatment suitable for an adhesive surface can be performed on the other side. With the present invention, the plate material 10 can, as described above, be used as a support tool to support one or more stiffeners 1 while both surfaces of the stiffener 1 are treated or while masking the side opposite from the side to be treated. This provides improved handling for the device.

When applying surface treatment, the outer perimeter end surface of the stiffener 1 is in contact with the plate material 10 because it has been re-fitted to the punched hole 10 of the plate material 10. As a result, the surface treatment can be prevented from bleeding over the outer perimeter end surface, and this prevention can be kept to less than 20% of the area of the outer perimeter end surface. As a result, stiffeners according to the present invention can be identified by studying the area of the outer perimeter end surface over which the surface treatment has reached.

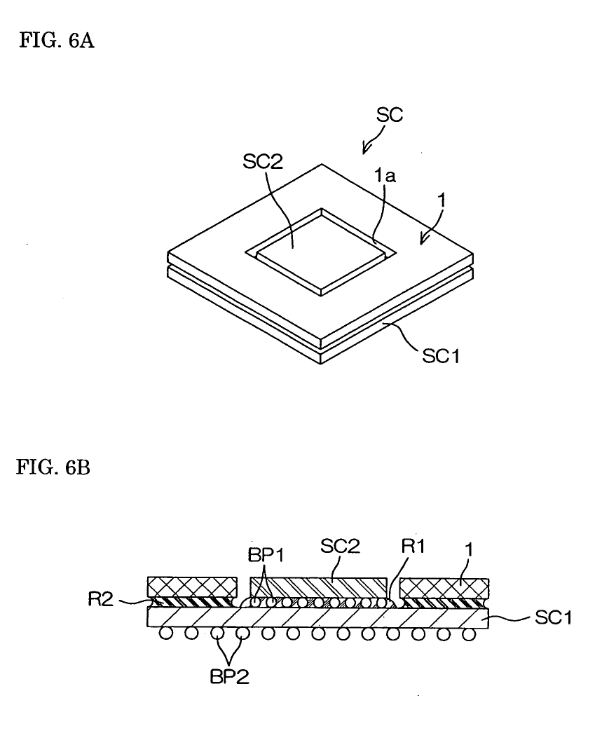

FIG. 6A is a perspective drawing of the exterior of a semiconductor device SC that uses the stiffener 1 according to the present invention. FIG. 6B is a cross-section drawing of the semiconductor device SC. As these figures show, in the semiconductor device SC in this example, a semiconductor element SC2 is mounted at the center, when seen from above in the figure, of the upper surface of a flat package SC1 via multiple solder balls BP1, which correspond to the individual electrodes of the semiconductor element SC2. A BGA, in which multiple solder balls BP2 corresponding to these electrodes are arranged in a grid pattern, is disposed at the bottom surface of the package SC1. Conductor circuits not shown in the figure are disposed on the top and bottom surfaces of the package SC1 to provide connections, e.g., one-to-one connections, between the solder balls BP1 and the solder balls BP2. The connecting section between the semiconductor element SC2 and the package SC1 formed by the solder balls BP1 is protected by being filled with an underfill R1.

In the stiffener 1, the through-hole 1a, as shown in the figures, is formed slightly larger than the outer shape of the semiconductor element SC2. The stiffener 1 is adhesed and secured using an adhesive R2 to the side of the package SC1 on which the semiconductor element SC2 is mounted so that it surrounds the semiconductor element SC2 and so that the adhesive surface is down and the display surface is up. As a result, the flatness of the package SC1, primarily in the BGA, is maintained, and heat dissipation of the package SC1 for heat from the semiconductor element SC2 is improved.

The structure of the present invention is not restricted to the examples in the figures described above.

For example, the stiffener 1 can be a flat structure that does not include the through-hole 1a at the center. This stiffener can be adhesed and secured to the side of the package opposite from the side on which the semiconductor element is mounted and the BGA is formed.

Various other changes can also be effected without departing from the spirit of the invention.

The embodiments of the present invention will be described.

### FIRST EMBODIMENT

A stainless steel plate (SUS 304, σ_{0.2}/σₘₐₓ ratio=0.52) having a thickness of 0.5 mm is used for the plate material 10. The plate material 10 is punched according to the conditions described below to form the flat shape shown in FIG. 1A, resulting in a stiffener 1 formed as a square having 40 mm sides with a square through-hole 1a having 20 mm sides.
Punch conditions
Punch pressure: 10 tons
Press rotation speed: 100 rpm

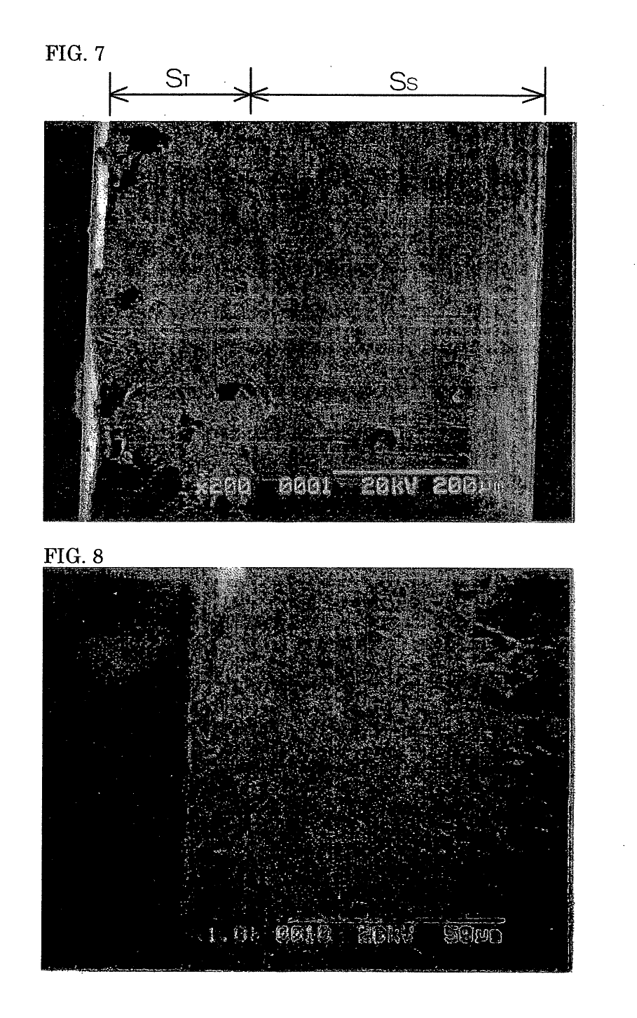

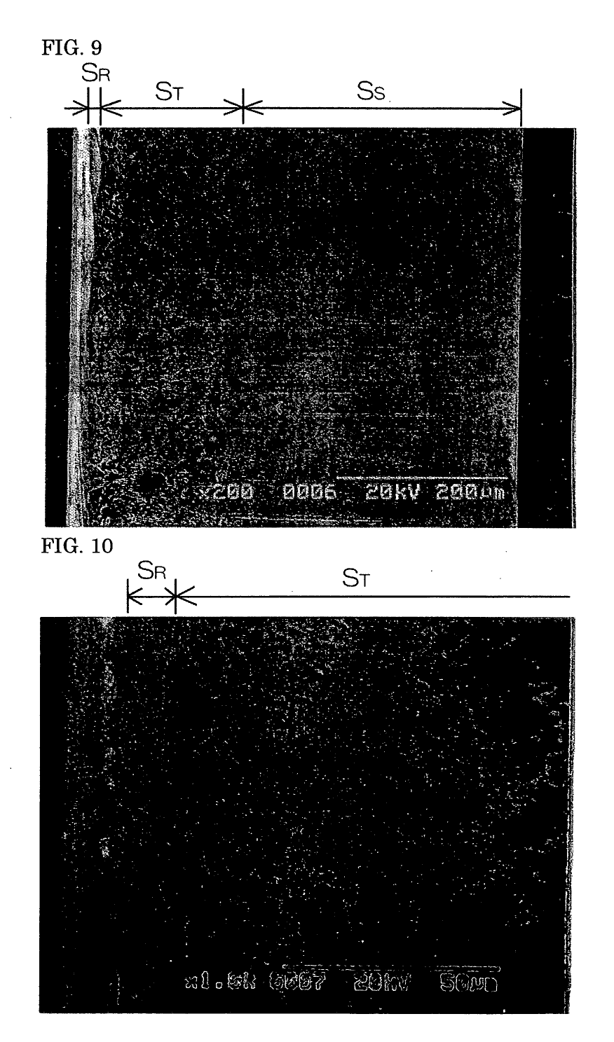

The outer perimeter end surface of the stiffener was observed immediately after punching using a scanning electron microscope. As shown in FIG. 7, approximately half of the thickness axis formed shear surfaces S_{S}, while the remaining sections formed fracture surfaces S_{T}. As shown in FIG. 8, the end sections (left end sections) of the fracture surfaces S_{T} projected in front of the photograph. Next, after re-fitting the stiffener 1 to the punched hole 10a of the plate material 10, it was removed from the plate material 10 and the outer perimeter end surface was observed using a scanning electron microscope. As shown in FIG. 9 and FIG. 10, the projected sections were worn off so that abraded surfaces SR extending along the thickness axis of the plate were formed.

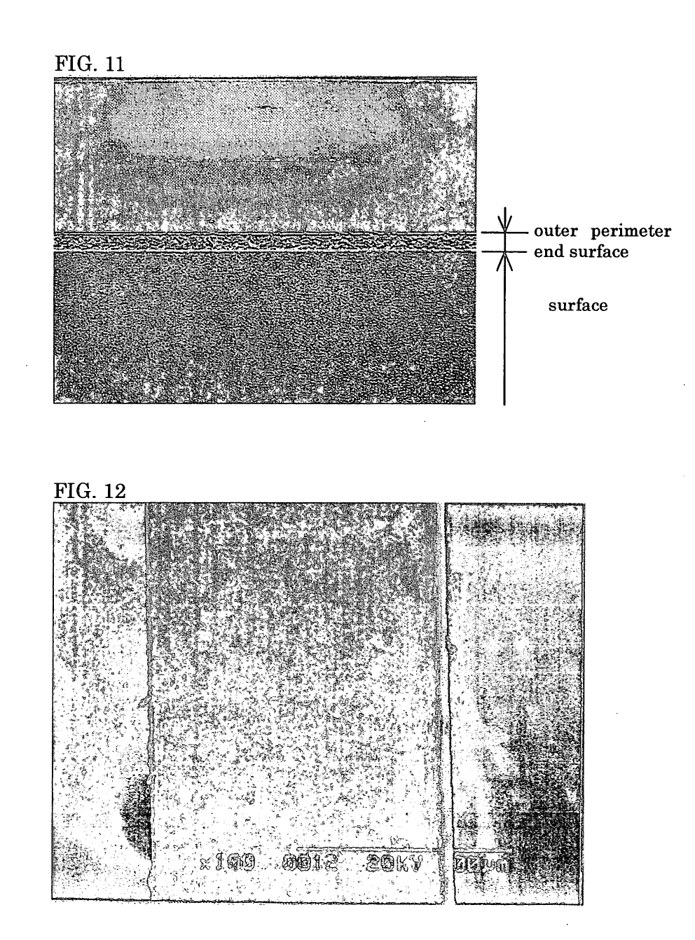

Also, with the stiffener 1 re-fitted to the punched hole 10a of the plate material 10, both sides were sandblasted and then one side was alodined. Then, the stiffener 1 was removed again from the plate material 10 and the outer perimeter end surface was observed using a scanning electron microscope. As shown in FIG. 11, the bleeding of the surface treatment to the outer perimeter end surface was no more than 20% of the area of the outer perimeter end surface even when surface treatment for both sides was added.

### SECOND EMBODIMENT

A plate 1.0 mm thick formed from an Al—SiC composite material (σ_{0.2}/σₘₐₓ ratio=0.95) was used. The plate material 10 was punched under the conditions described below, resulting in the stiffener 1 with the flat shape shown in FIG. 1A forming a square with 44.6 mm sides and including the square through-hole 1a with 35 mm sides.

Punching Conditions

Punching pressure: 6 tons
Press rotation speed: 100 rpm

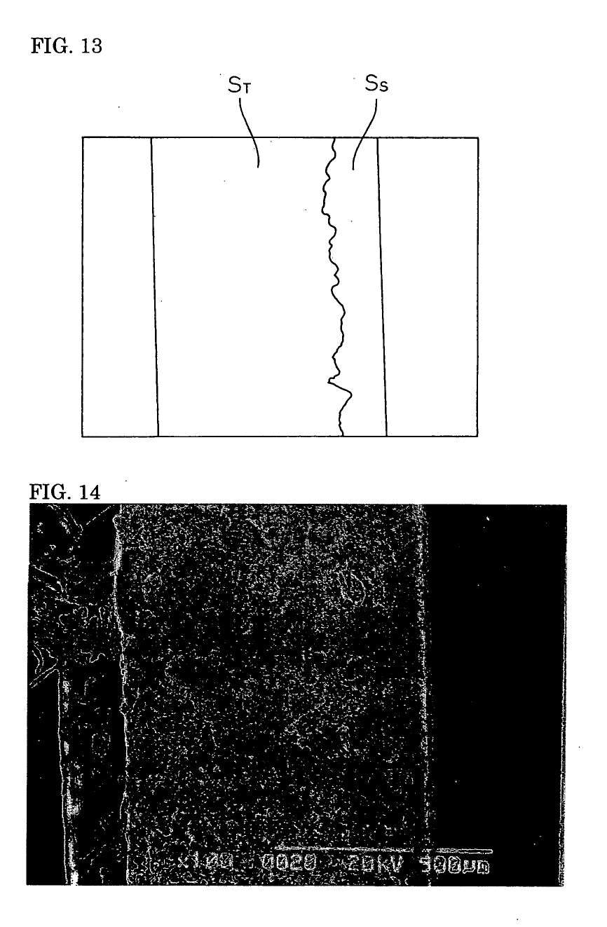

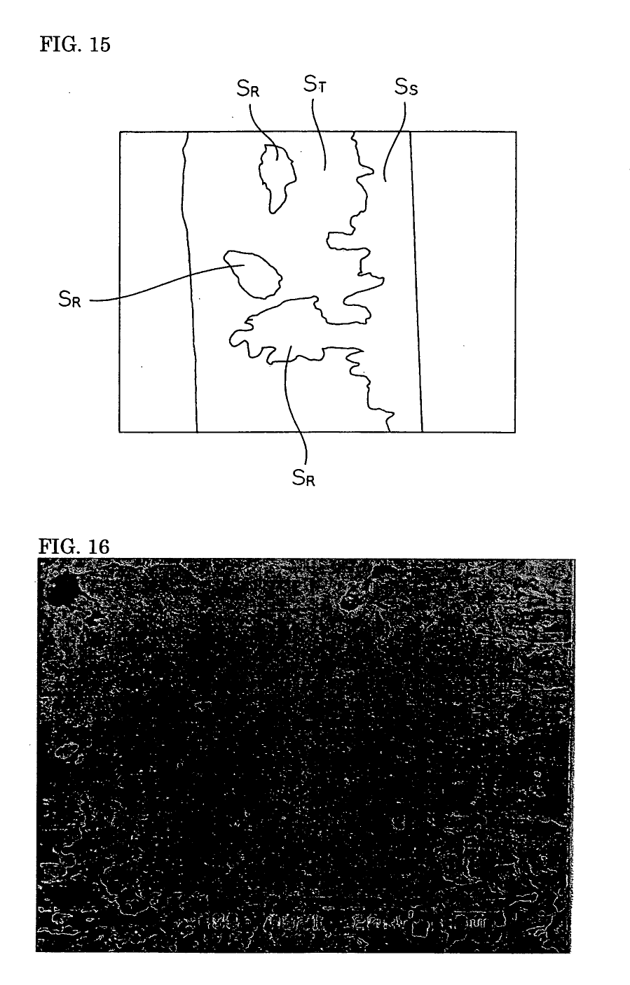

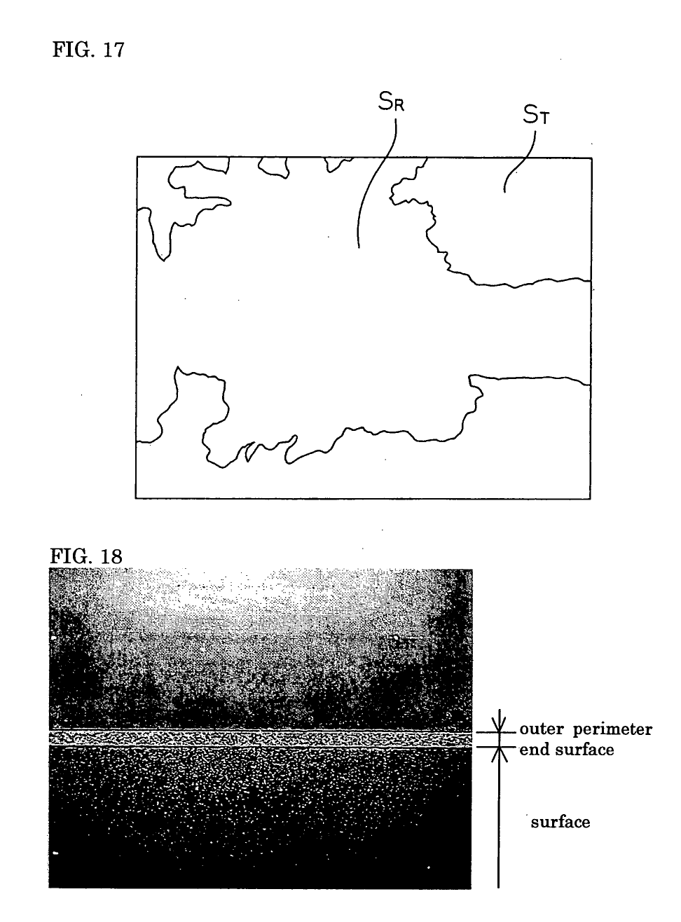

The outer perimeter end surface of the stiffener was observed using a scanning electron microscope right after punching. As shown in FIG. 12 and FIG. 13, approximately 1/5 of the thickness axis formed shear surfaces S_{S}, while the remainder formed fracture surfaces S_{T}. Next, the stiffener 1 was re-fitted to the punched hole 10a, removed from the plate material 10, and examined under a scanning electron microscope. As shown in FIG. 14 and FIG. 15, the projections in the fracture surface S_{T} were worn off so that, as shown in FIG. 16 and FIG. 17, abraded surfaces S_{R} extending along the thickness axis of the plate were observed.

With the stiffener 1 re-fitted to the punched hole 10a, high-pressure washing was applied to both surfaces to remove surface oil. Next, one surface was alumetized, the stiffener 1 was removed from the plate material 10 again, and the outer perimeter end surface was observed with a scanning electron microscope. As shown in FIG. 18, the bleeding of the surface treatment to the outer perimeter end surface was no more than 20% of the area of the outer perimeter end surface even when surface treatment for both sides was added.

Having described preferred embodiments of the invention with reference to the accompanying drawings, it is to be understood that the invention is not limited to those precise embodiments, and that various changes and modifications may be effected therein by one skilled in the art without departing from the scope or spirit of the invention as defined in the appended claims.

1. A flat stiffener used to reinforce a semiconductor device,
wherein:said stiffener is formed in a predetermined flat shape from a plate by punching; and
said stiffener has an outer perimeter end surface which is formed with shear surfaces and fracture surfaces created by said punching operations and abraded surfaces extending along the thickness axis of said plate created by abrasion of projections on said fracture surfaces.

2. The stiffener according to claim 1 on which surface treatment is applied to both surfaces of said plate.

3. The stiffener according to claim 2 on which different surface treatments are applied to said surfaces of said plate.

4. The stiffener according to claim 2 wherein at least one type of surface treatment selected from the group consisting of sandblasting, high-pressure washing, Ni plating; zinc plating, chromating, alumetizing, alodining, Au plating, and oxide film application is applied to said surfaces of said plate.

5. The stiffener according to claim 2 wherein bleeding of said surface treatment to said outer perimeter end surface is less than 20% of the area of said outer perimeter end surface.

6. The stiffener according to claim 1 wherein said stiffener is formed from Fe, Cu, Al, an alloy of said metals, or a compound containing said metals.

7. A method for making a stiffener comprising the steps of: punching a plate to form a stiffener having a predetermined flat shape;
re-fitting said formed stiffener in a punched hole in said plate;
applying a surface treatment to at least one side of said stiffener that has been re-fitted and integrated with said plate material; and
removing said stiffener from said plate material after the surface treatment.

8. The method according to claim 7 wherein the surface treatment is applied to both surfaces of said plate.

9. The method according to claim 7 wherein different types of surface treatment are applied to said surfaces of said plate.

10. The method according to claim 7 wherein at least one type of surface treatment selected from the group consisting of sandblasting high-pressure washing, Ni plating, zinc plating, chromating, alumetizing, alodining, Au plating, and oxide film application, is applied to said surfaces of said plate, said types of surface treatment.

11. The method according to claim 7 wherein bleeding of said surface treatment to said outer perimeter end surface is less than 20% of the area of said outer perimeter end surface.

12. The method according to claim 7 wherein the stiffener is formed from Fe, Cu, Al, an alloy of said metals, or a compound containing said metals.

13. A semiconductor device comprising:
a stiffener for reinforcing the semiconductor device,
wherein said stiffener is formed in a predetermined flat shape from a plate by punching; and said stiffener has an outer perimeter end surface which is formed with shear surfaces and fracture surfaces created by said punching operations and abraded surfaces extending along the thickness axis of said plate created by abrasion of projections on said fracture surfaces.

14. The semiconductor device according to claim 13, wherein the surface treatment is applied to both surfaces of said plate.

15. The semiconductor device according to claim 14 wherein different types of surface treatment are applied to said surfaces of said plate.

16. The semiconductor device according to claim 14 wherein at least one type of surface treatment selected from the group consisting of sandblasting high-pressure washing, Ni plating, zinc plating, chromating; alumetizing, alodining, Au plating, and oxide film application, is applied to said surfaces of said plate.

17. The semiconductor device according to claim 14 wherein bleeding of said surface treatment to said outer perimeter end surface is less than 20% of the area of said outer perimeter end surface.
